(19) United States
(12) Patent Application Publication
(10) Pub. No.: US 2024/0264389 A1
(43) Pub. Date: Aug. 8, 2024

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chao-Chiang PU, Taichung City (TW); Chi-Ching HO, Taichung City (TW); Yi-Min FU, Taichung City (TW); Che-Yu LEE, Taichung City (TW); Po-Yuan SU, Taichung City (TW)

(21) Appl. No.: 18/310,635

(22) Filed: May 2, 2023

(30) Foreign Application Priority Data
Feb. 3, 2023 (TW) 112103913

(51) Int. Cl. G02B 6/42; H01L 23/00; H01L 23/31; H01L 25/16

(52) U.S. Cl. CPC G02B 6/4243; G02B 6/4251; H01L 23/3185; H01L 24/19; H01L 24/20; H01L 25/16; H01L 2224/19; H01L 2224/211; H01L 2224/215; H01L 2924/01029

(57) ABSTRACT

An electronic package and the manufacturing method thereof are provided, in which a photonic element and an electronic element are embedded in an encapsulation layer, and the photonic element has an external contact area exposed from the encapsulation layer, such that signals of the electronic element can be directly transmitted to an optical fiber via the external contact area of the photonic element to achieve the purpose of photoelectric integration.

### BACKGROUND

### 1. Technical Field

The present disclosure relates to a semiconductor device, and more particularly, to an electronic package with a photonic element and the manufacturing method thereof.

### 2. Description of Related Art

With the vigorous development of the electronic industry, electronic products are gradually developing towards the trend of multi-function and high performance. At present, the application of the fifth generation (5G) communication technology has been extended to the Internet of Things (IoT), Industrial Internet of Things (IIoT), Cloud, artificial intelligence (AI), autonomous car, medical and other fields, and with the expansion of the application level, a very large amount of data will be generated in the process to be efficiently transmitted, calculated and stored. Therefore, in recent years, large-scale data centers and cloud servers have a large demand for data transmission, and the industry has begun to enter the field of optical communication, using “light” instead of “electricity” as the carrier of data transmission.

FIG. 1A to FIG. 1E are schematic cross-sectional views illustrating a method of manufacturing a conventional semiconductor package 1 using wafer-level packaging technology.

As shown in FIG. 1A, a thermal release layer 100 (e.g., a thermal release tape) is formed on a carrier 10.

Then, a plurality of communication chips 11 are disposed on the thermal release layer 100. The plurality of communication chips 11 have active surfaces 11a and inactive surfaces 11b opposing the active surfaces 11a. A plurality of electrode pads 110 are formed on each of the active surfaces 11a, and each of the active surfaces 11a is adhered on the thermal release layer 100.

As shown in FIG. 1B, an encapsulant 14 is formed on the thermal release layer 100 to cover the plurality of communication chips 11.

As shown in FIG. 1C, the encapsulant 14 is baked to harden the thermal release layer 100, and then the thermal release layer 100 and the carrier 10 are removed to expose the active surfaces 11a of the plurality of communication chips 11.

As shown in FIG. 1D, a circuit structure 16 is formed on the encapsulant 14 and the active surfaces 11a of the plurality of communication chips 11, so that the circuit structure 16 is electrically connected to the electrode pads 110. Next, an insulating protective layer 18 is formed on the circuit structure 16, and parts of a surface of the circuit structure 16 are exposed from the insulating protective layer 18 for bonding conductive elements 17 such as solder balls.

As shown in FIG. 1E, a singulation process is performed along cutting paths L shown in FIG. 1D to obtain a plurality of the semiconductor packages 1.

With the evolution of technology, optical communication can increase transmission capacity/efficiency/distance to increase data bandwidth and reduce unit energy consumption. Therefore, silicon photonic elements and their application products have been emphasized and developed again.

However, the conventional semiconductor package 1 is equipped without a silicon photonic chip, so that a silicon photonic chip needs to be arranged on a circuit board to connect with an external optical fiber, but this would make the signal transmission path between the communication chip 11 and the optical fiber lengthy, so the transmission speed (100 Gbps) of an optical fiber communication equipment applied with the semiconductor package 1 is difficult to increase and is gradually becoming inadequate.

Therefore, how to integrate photonic elements into the packaging process has become an urgent problem to be overcome in the industry.

### SUMMARY

In view of the aforementioned shortcomings of the prior art, the present disclosure provides an electronic package, which comprises: an encapsulation layer having a first surface, a second surface opposing the first surface, and a side surface adjacent to the first surface and the second surface; a photonic element embedded in the encapsulation layer and disposed on the first surface of the encapsulation layer, wherein a part of a surface of the photonic element protrudes from the side surface to be used as an external contact area, and the external contact area has an electrical port; and an electronic element embedded in the encapsulation layer and disposed on the first surface of the encapsulation layer, wherein the electronic element is electrically connected to the photonic element.

The present disclosure also provides a method of manufacturing an electronic package, the method comprises: disposing a photonic element and an electronic element on a carrier, wherein the photonic element has an external contact area, and the external contact area has an electrical port; forming an encapsulation layer on the carrier to cover the photonic element and the electronic element, wherein the encapsulation layer has a first surface and a second surface opposing the first surface, and the encapsulation layer is bonded onto the carrier via the first surface of the encapsulation layer; and removing the carrier to expose the first surface of the encapsulation layer, wherein the encapsulation layer has a side surface adjacent to the first surface and the second surface, and the external contact area of the photonic element protrudes from the side surface.

In the aforementioned electronic package and method, the present disclosure further comprises forming a circuit structure on the first surface of the encapsulation layer, wherein the circuit structure is electrically connected to the electronic element and the photonic element. For example, the circuit structure is of a redistribution layer specification or a substrate specification.

In the aforementioned electronic package and method, the external contact area is in a shape of a notch or a groove.

In the aforementioned electronic package and method, the external contact area is connected to an optical fiber, and the electrical port is electrically connected to the optical fiber.

In the aforementioned electronic package and method, the present disclosure further comprises forming a plurality of conductive elements on the first surface of the encapsulation layer, wherein the plurality of conductive elements are connected to an electronic device.

In the aforementioned electronic package and method, the photonic element has a functional surface and a back surface opposing the functional surface, wherein the functional surface corresponds to the first surface of the encapsulation layer, and at least one electrical contact is disposed on the functional surface. For example, the back surface of the photonic element is flush with the second surface of the encapsulation layer. Alternatively, the external contact area is correspondingly formed on the functional surface or the back surface.

As can be understood from the above, in the electronic package and manufacturing method thereof according to the present disclosure, the photonic element and the electronic element are embedded in the encapsulation layer to achieve the purpose of optoelectronic integration, so that the signals of the electronic element can be directly transmitted to the optical fiber via the external contact area of the photonic element. Therefore, compared with the prior art, the electronic package of the present disclosure can greatly reduce the signal transmission path between the electronic element and the optical fiber, so as to effectively speed up the signal transmission speed and thus meet the performance requirements of the electronic package for fast operation.

### BRIEF DESCRIPTION OF THE DRAWINGS

FIG. 1A to FIG. 1E are schematic cross-sectional views illustrating a method of manufacturing a conventional semiconductor package.

FIG. 2A to FIG. 2F are schematic cross-sectional views illustrating a method of manufacturing an electronic package of the present disclosure.

FIG. 2G is a schematic cross-sectional view showing a subsequent process of FIG. 2F.

FIG. 3A, FIG. 3B and FIG. 3C are schematic cross-sectional views showing different aspects of FIG. 2F.

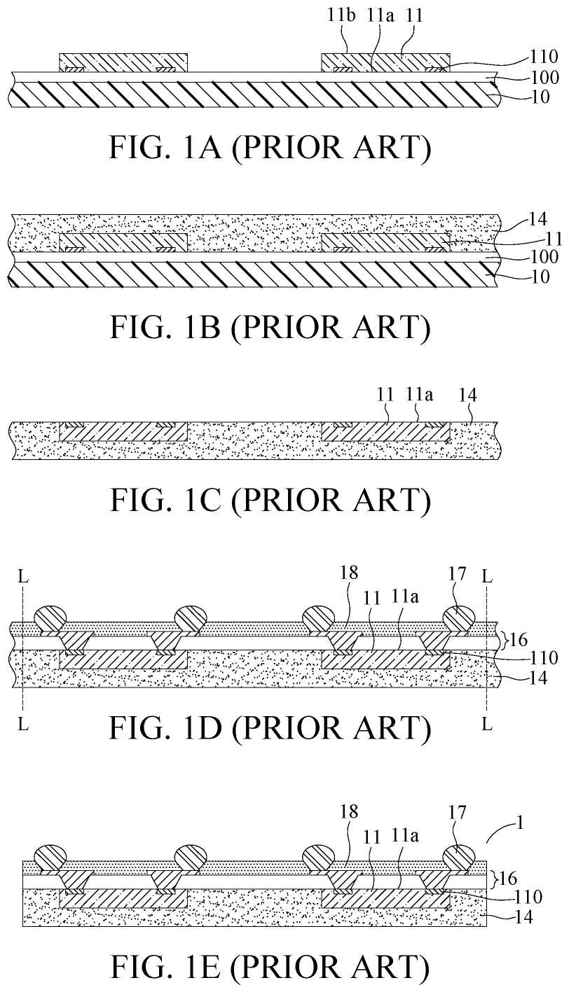

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

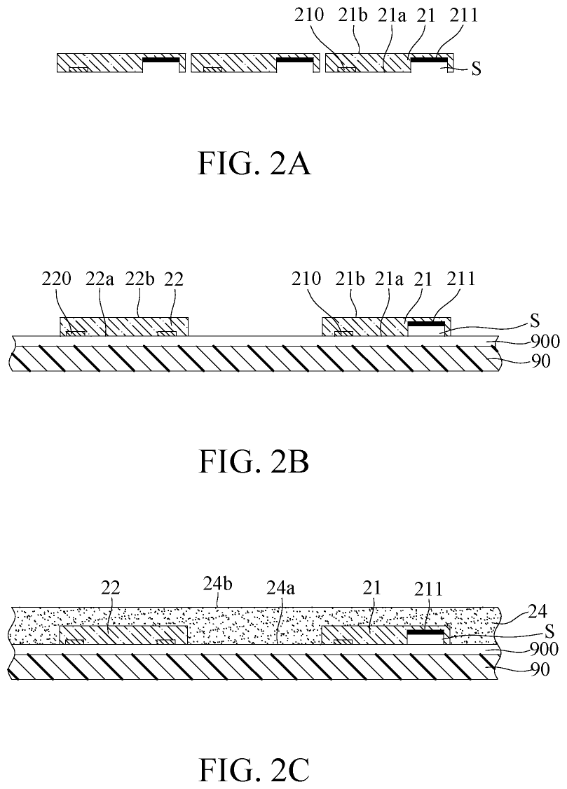

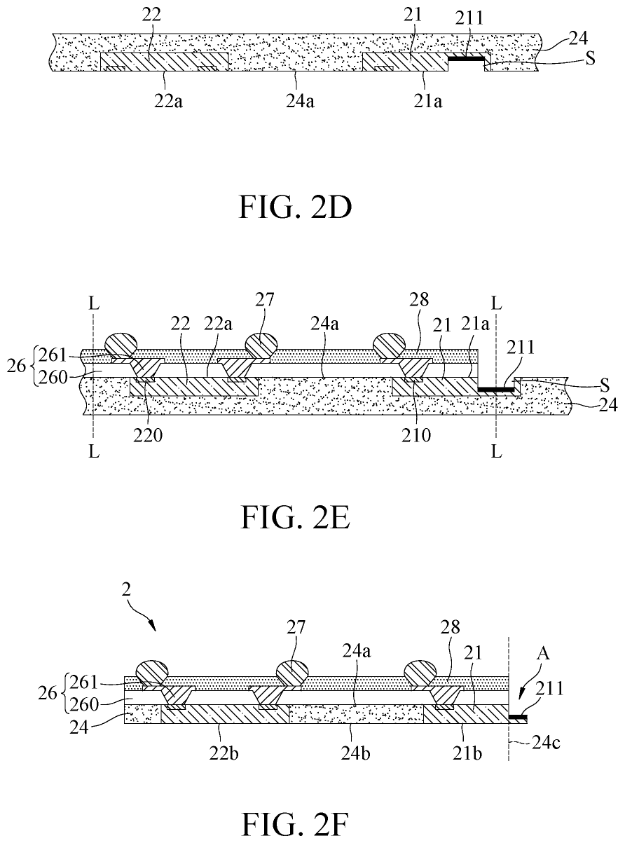

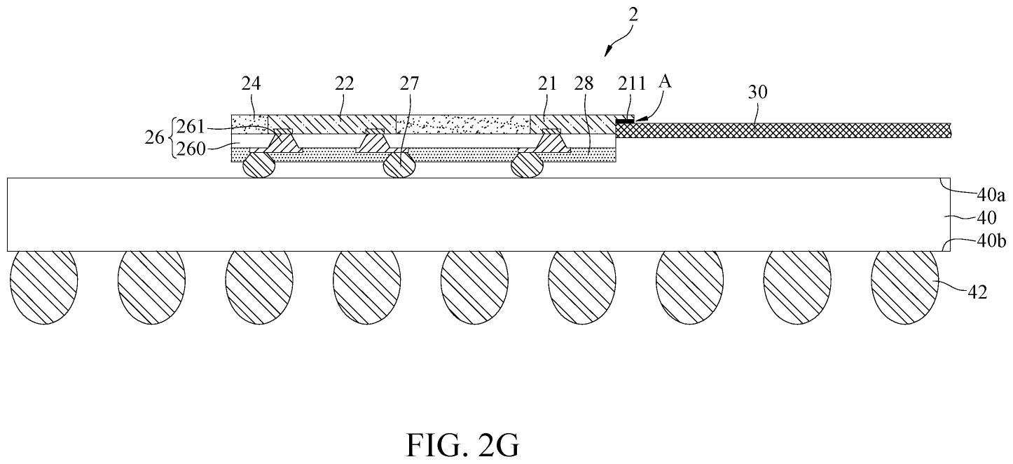

FIG. 2A to FIG. 2F are schematic cross-sectional views illustrating a method of manufacturing an electronic package 2 of the present disclosure.

As shown in FIG. 2A, a singulation process is performed to a semiconductor substrate comprising a plurality of photonic elements 21 (e.g., photonic dies) arranged in an array so as to obtain the plurality of photonic elements 21 with recesses S.

In an embodiment, the photonic element 21 has a functional surface 21a and a back surface 21b opposing the functional surface 21a, wherein at least one electrical contact 210 is formed on the functional surface 21a, and the recess S is formed on the functional surface 21a, so that an electrical port 211 is formed in the recess S, wherein the electrical contact 210 and the electrical port 211 are electrically connected to each other.

As shown in FIG. 2B, a carrier 90 with a thermal release layer 900 (e.g., a thermal release tape) is provided. Then, the photonic element 21 and at least one electronic element 22 are disposed on the thermal release layer 900.

In an embodiment, the photonic element 21 is bonded onto the thermal release layer 900 via the functional surface 21a of the photonic element 21.

Moreover, the electronic element 22 is an active element, a passive element, or a combination of the active element and the passive element, wherein the active element is such as a semiconductor chip, and the passive element is such as a resistor, a capacitor, or an inductor. For example, the electronic element 22 is a semiconductor chip and has an active surface 22aand an inactive surface 22b opposing the active surface 22a. A plurality of electrode pads 220 are formed on the active surface 22a, so that the electronic element 22 is bonded onto the thermal release layer 900 via the active surface 22a of the electronic element 22.

As shown in FIG. 2C, an encapsulation layer 24 is formed on the thermal release layer 900 to cover the photonic element 21 and the electronic element 22, wherein the encapsulation layer 24 has a first surface 24a and a second surface 24b opposing the first surface 24a, so that the encapsulation layer 24 is bonded onto the thermal release layer 900 via the first surface 24a of the encapsulation layer 24.

In an embodiment, the encapsulation layer 24 is made of an insulating material, such as polyimide (PI), dry film, molding colloid or molding compound such as epoxy resin. For example, the encapsulation layer 24 can be formed on the thermal release layer 900 by liquid compound, injection, lamination, or compression molding.

As shown in FIG. 2D, the carrier 90 and the thermal release layer 900 on the carrier 90 are removed to expose the first surface 24a of the encapsulation layer 24, so that the functional surface 21a of the photonic element 21 and the active surface 22a of the electronic element 22 are exposed from the first surface 24a of the encapsulation layer 24.

In an embodiment, the thermal release layer 900 is hardened by baking the encapsulation layer 24, such that the thermal release layer 900 and the carrier 90 can be easily removed to expose the first surface 24a of the encapsulation layer 24.

As shown in FIG. 2E, a circuit structure 26 is formed on a part of the first surface 24a of the encapsulation layer 24, wherein the encapsulation layer 24 is free from being entirely covered by the circuit structure 26, and a part of the first surface 24a of the encapsulation layer 24 is exposed from the circuit structure 26, wherein the circuit structure 26 is electrically connected to the photonic element 21 and the electronic element 22, so that the signals of the electronic element 22 can be transmitted to the photonic element 21 via the circuit structure 26.

In an embodiment, the circuit structure 26 has at least one dielectric layer 260 and at least one circuit layer 261 bonded to the dielectric layer 260 and electrically connected to the electrical contact 210 and the electrode pads 220 (e.g., the circuit structure 26 is of a redistribution layer [RDL] specification). For example, the material forming the circuit layer 261 is copper, and the material forming the dielectric layer 260 is such as polybenzoxazole (PBO), polyimide (PI), prepreg (PP), or other dielectric materials.

Furthermore, an insulating protective layer 28 such as a solder-resist layer can be formed on the outermost dielectric layer 260 of the circuit structure 26, and a part of the surface of the outermost circuit layer 261 of the circuit structure 26 is exposed from the insulating protective layer 28 and is used as electrical contact pads to bond a plurality of conductive elements 27 such as solder balls.

It should be understood that the circuit structure 26 can also be of a substrate specification. For instance, the circuit structure 26 can be a package substrate with a core layer and a routing layer or a coreless package substrate, and the circuit structure 26 can be disposed on the first surface 24a of the encapsulation layer 24 via an adhesive method.

In addition, the recess S of the photonic element 21 is free from being covered by the circuit structure 26, such that the electrical port 211 is exposed from the circuit structure 26.

As shown in FIG. 2F, a singulation process is performed along cutting paths L shown in FIG. 2E to obtain a plurality of the electronic packages 2.

In an embodiment, the cutting path L passes through the recess S of the photonic element 21, so that after the singulation process, the photonic element 21 and the electrical port 211 of the photonic element 21 protrude from a side surface 24c of the encapsulation layer 24 to be used as an external contact area A (e.g., an external connection area) of the electronic package 2.

Moreover, a leveling process can be performed to remove part of the material of the second surface 24b of the encapsulation layer 24, so that the back surface 21b of the photonic element 21 and the inactive surface 22b of the electronic element 22 are flush with the second surface 24b of the encapsulation layer 24, such that the back surface 21b of the photonic element 21 and the inactive surface 22b of the electronic element 22 are exposed from the second surface 24b of the encapsulation layer 24. For example, part of the material of the second surface 24b of the encapsulation layer 24 can be removed by grinding.

Also, in a subsequent process, as shown in FIG. 2G, the electrical port 211 can be connected to at least one optical fiber 30 according to requirements, so that the optical fiber 30 is electrically connected to the electrical port 211, and the electronic package 2 can be disposed on an electronic device 40 such as a circuit board via the conductive elements 27. For example, the electronic device 40 has a first side 40a and a second side 40b opposing the first side 40a, so that the electronic package 2 is disposed on the first side 40a of the electronic device 40 via the conductive elements 27 of the electronic package 2, and the electronic package 2 is electrically connected to circuits of the electronic device 40. Further, a plurality of solder balls 42 can be bonded on the second side 40b of the electronic device 40 for connecting to a circuit board (not shown). It should be understood that the electronic package 2 can also be directly disposed on the circuit board via the conductive elements 27.

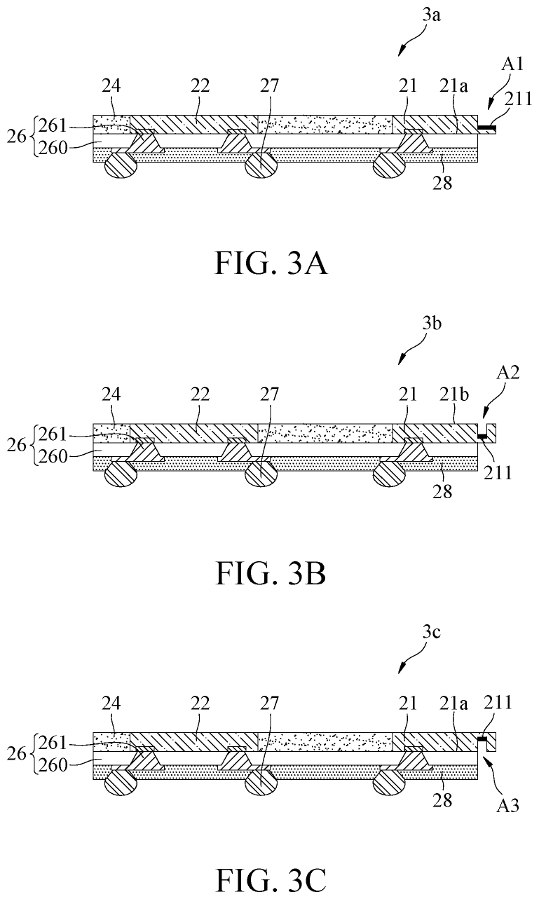

In an embodiment, the external contact area A is formed on the back surface 21b of the photonic element 21 and is in the shape of a notch, and the electrical port 211 faces toward the functional surface 21a. In other embodiments, in an electronic package 3a shown in FIG. 3A, an external contact area A1 can also be formed on the functional surface 21a of the photonic element 21, and the electrical port 211 faces toward the back surface 21b. It should be understood that, in an electronic package 3b shown in FIG. 3B or in an electronic package 3c shown in FIG. 3C, if the cutting path L does not pass through the recess S of the photonic element 21, an external contact area A2, A3 is in the shape of a groove after the singulation process is performed, and the external contact area A2 is formed on the back surface 21b of the photonic element 21 in the electronic package 3b as shown in FIG. 3B, or the external contact area A3 is formed on the functional surface 21a in the electronic package 3c as shown in FIG. 3C, wherein the electrical port 211 is formed at the bottom of the groove.

Therefore, in the manufacturing method according to the present disclosure, the photonic element 21 and the electronic element 22 are embedded in the encapsulation layer 24 to achieve the purpose of optoelectronic integration, so that the signals of the electronic element 22 can be directly transmitted to the optical fiber 30 via the external contact area A, A1, A2, A3 of the photonic element 21. Therefore, compared with the prior art, the electronic package 2 of the present disclosure can greatly reduce the signal transmission path between the electronic element 22 and the optical fiber 30, so as to effectively speed up the signal transmission speed and thus meet the performance requirements of the electronic package 2 for fast operation, thereby the electronic products using the electronic package 2 are competitive in the consumer market.

Furthermore, with the design of the recess S, the external contact area A, A1, A2, A3 such as a notch or a groove is formed, so that the electrical port 211 can avoid the problem of being bumped against by external objects.

Also, the external contact area A, A1, A2, A3 is designed in the form of a notch or a groove, so as to facilitate the alignment of the optical fiber 30 to the electrical port 211 and facilitate connection to the photonic element 21.

The present disclosure further provides an electronic package 2, 3a, 3b, 3c, which comprises a photonic element 21, an electronic element 22 and an encapsulation layer 24.

The encapsulation layer 24 has a first surface 24a, a second surface 24b opposing the first surface 24a, and a side surface 24c adjacent to the first surface 24a and the second surface 24b.

The photonic element 21 is embedded in the encapsulation layer 24 and disposed on the first surface 24a of the encapsulation layer 24, wherein the photonic element 21 protrudes from the side surface 24c to be used as an external contact area A, A1, A2, A3, and the external contact area A, A1, A2, A3 has an electrical port 211.

The electronic element 22 is embedded in the encapsulation layer 24 and disposed on the first surface 24a of the encapsulation layer 24, wherein the electronic element 22 is electrically connected to the photonic element 21.

In one embodiment, a circuit structure 26 is disposed on the first surface 24a of the encapsulation layer 24, so that the circuit structure 26 is electrically connected to the electronic element 22 and the photonic element 21. For example, the circuit structure 26 is of a redistribution layer specification or a substrate specification.

In one embodiment, the external contact area A, A1 is in a shape of a notch.

In one embodiment, the external contact area A2, A3 is in a shape of a groove.

In one embodiment, the external contact area A, A1, A2, A3 is connected to an optical fiber 30, so that the electrical port 211 is electrically connected to the optical fiber 30.

In one embodiment, a plurality of conductive elements 27 are disposed on the first surface 24a of the encapsulation layer 24, so that the plurality of conductive elements 27 are connected to an electronic device 40.

In one embodiment, the photonic element 21 has a functional surface 21a and a back surface 21b opposing the functional surface 21a, so that the functional surface 21a corresponds to the first surface 24a of the encapsulation layer 24. For example, the back surface 21b of the photonic element 21 is flush with the second surface 24b of the encapsulation layer 24. Alternatively, the external contact area A, A1, A2, A3 is correspondingly formed on the functional surface 21a or the back surface 21b.

In view of the above, in the electronic package and manufacturing method thereof according to the present disclosure, the photonic element and the electronic element are embedded in the encapsulation layer to achieve the purpose of optoelectronic integration, so that the signals of the electronic element can be directly transmitted to the optical fiber via the external contact area of the photonic element. Therefore, the electronic package of the present disclosure can greatly reduce the signal transmission path between the electronic element and the optical fiber, so as to effectively speed up the signal transmission speed and thus meet the performance requirements of the electronic package for fast operation.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
an encapsulation layer having a first surface, a second surface opposing the first surface, and a side surface adjacent to the first surface and the second surface;
a photonic element embedded in the encapsulation layer and disposed on the first surface of the encapsulation layer, wherein a part of a surface of the photonic element protrudes from the side surface to be used as an external contact area, and the external contact area has an electrical port; and
an electronic element embedded in the encapsulation layer and disposed on the first surface of the encapsulation layer, wherein the electronic element is electrically connected to the photonic element.

2. The electronic package of claim 1, further comprising a circuit structure formed on the first surface of the encapsulation layer, wherein the circuit structure is electrically connected to the electronic element and the photonic element.

3. The electronic package of claim 2, wherein the circuit structure is of a redistribution layer specification or a substrate specification.

4. The electronic package of claim 1, wherein the external contact area is in a shape of a notch.

5. The electronic package of claim 1, wherein the external contact area is in a shape of a groove.

6. The electronic package of claim 1, wherein the external contact area is connected to an optical fiber, and the electrical port is electrically connected to the optical fiber.

7. The electronic package of claim 1, further comprising a plurality of conductive elements formed on the first surface of the encapsulation layer, wherein the plurality of conductive elements are connected to an electronic device.

8. The electronic package of claim 1, wherein the photonic element has a functional surface and a back surface opposing the functional surface, wherein the functional surface corresponds to the first surface of the encapsulation layer, and at least one electrical contact is disposed on the functional surface.

9. The electronic package of claim 8, wherein the back surface of the photonic element is flush with the second surface of the encapsulation layer.

10. The electronic package of claim 8, wherein the external contact area is correspondingly formed on the functional surface or the back surface.

11. A method of manufacturing an electronic package, comprising:
disposing a photonic element and an electronic element on a carrier, wherein the photonic element has an external contact area, and the external contact area has an electrical port;
forming an encapsulation layer on the carrier to cover the photonic element and the electronic element, wherein the encapsulation layer has a first surface and a second surface opposing the first surface, and the encapsulation layer is bonded onto the carrier via the first surface of the encapsulation layer; and
removing the carrier to expose the first surface of the encapsulation layer, wherein the encapsulation layer has a side surface adjacent to the first surface and the second surface, and the external contact area of the photonic element protrudes from the side surface.

12. The method of claim 11, further comprising forming a circuit structure on the first surface of the encapsulation layer, wherein the circuit structure is electrically connected to the electronic element and the photonic element.

13. The method of claim 12, wherein the circuit structure is of a redistribution layer specification or a substrate specification.

14. The method of claim 11, wherein the external contact area is in a shape of a notch.

15. The method of claim 11, wherein the external contact area is in a shape of a groove.

16. The method of claim 11, wherein the external contact area is connected to an optical fiber, and the electrical port is electrically connected to the optical fiber.

17. The method of claim 11, further comprising forming a plurality of conductive elements on the first surface of the encapsulation layer, wherein the plurality of conductive elements are connected to an electronic device.

18. The method of claim 11, wherein the photonic element has a functional surface and a back surface opposing the functional surface, wherein the functional surface corresponds to the first surface of the encapsulation layer, and at least one electrical contact is disposed on the functional surface.

19. The method of claim 18, wherein the back surface of the photonic element is flush with the second surface of the encapsulation layer.

20. The method of claim 18, wherein the external contact area is correspondingly formed on the functional surface or the back surface.
